(19) United States
(12) Patent Application Publication
(10) Pub. No.: US 2007/0096290 A1
(43) Pub. Date: May 3, 2007

(54) Active device bases and leadframes utilizing the same

(75) Inventor: Chien-Chen Lee, Hsinchu County (TW)

Correspondence Address: QUINTERO LAW OFFICE, PC, 2210 MAIN STREET, SUITE 200, SANTA MONICA, CA, 90405, US

(73) Assignee: AIROHA TECHNOLOGY CORP., HSINCHU (TW)

(21) Appl. No.: 11/348,858

(22) Filed: Feb. 6, 2006

(30) Foreign Application Priority Data
Nov. 1, 2005 (TW) TW94138242

(51) Int. Cl. H01L 23/48

(52) U.S. Cl. 257/690

(57) ABSTRACT

An active device base and a leadframe utilizing the base. The base includes a plate, a predetermined attachment area for an active device on a surface of the plate, and at least one through hole in the plate, beyond the predetermined attachment region.

### BACKGROUND OF THE INVENTION

1. Field of the Invention

The invention relates to package technology and in particular to active device bases and leadframes utilizing the same.

2. Description of the Related Art

FIG. 1 is a cross-section of a conventional package utilizing a leadframe having an active device base 10 and terminals 20 serving as a package substrate. Wires 32 electrically connect the terminals and a chip 30 attached to the active device base 10. The chip 30 and wires 40 are encapsulated by an encapsulant 40.

In FIG. 1, thermal stress induced by reliability tests standardized by Joint Electronic Engineering Council (JDEC) can typically damage the interface between the chip 30 and active device base 10, resulting in delamination therebetween, resulting in rejection of the package.

Environmental concerns have lead countries or economies to increasingly request processes not utilizing lead. The soldering temperature of unleaded solder is at least 40° C. higher than that of tin-lead eutectic solder, resulting in critical requests for reliable green electronic products. Thus, development of a more reliable package utilizing a leadframe is desirable.

### BRIEF SUMMARY OF THE INVENTION

Active device bases and leadframes utilizing the same are provided.

The invention provides an active device base comprising a plate, predetermined attachment area for an active device, and at least one through hole. The predetermined attachment area is disposed on a surface of the plate. The through hole is disposed in the plate, beyond the predetermined attachment area.

The invention further provides a leadframe comprising a plate, a predetermined attachment area for an active device, at least one through hole, a plurality of terminals, and a peripheral boundary. The predetermined attachment area is disposed on a surface of the plate. The through hole is disposed in the plate, beyond the predetermined attachment area. The terminals are beyond the plate. The peripheral boundary sandwiches the terminals with the plate, and is connected to the respective plate and the terminals.

Further scope of the applicability of the invention will become apparent from the detailed description given hereinafter. It should be understood, however, that the detailed description and specific examples, while indicating preferred embodiments of the invention, are given by way of illustration only, since various changes and modifications within the spirit and scope of the invention will become apparent to those skilled in the art from this detailed description.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a cross-section of a conventional package;

FIG. 2 is a top view of an active device base and a leadframe of a preferred embodiment of the invention;

FIG. 3 is a cross-section along line AA in FIG. 2; and

FIG. 4 is a cross-section showing advantages of the active device base and the leadframe of the invention.

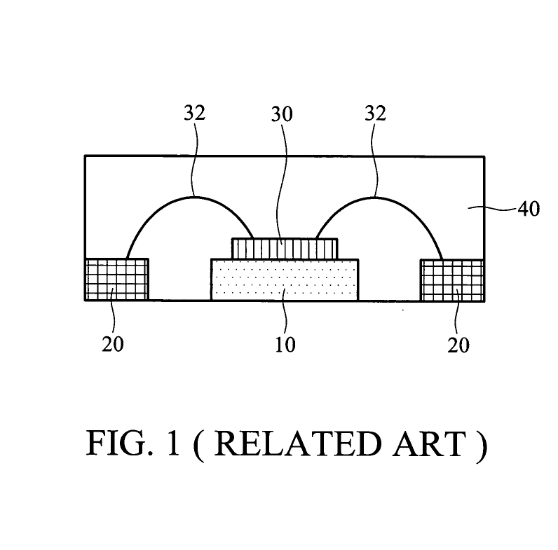

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

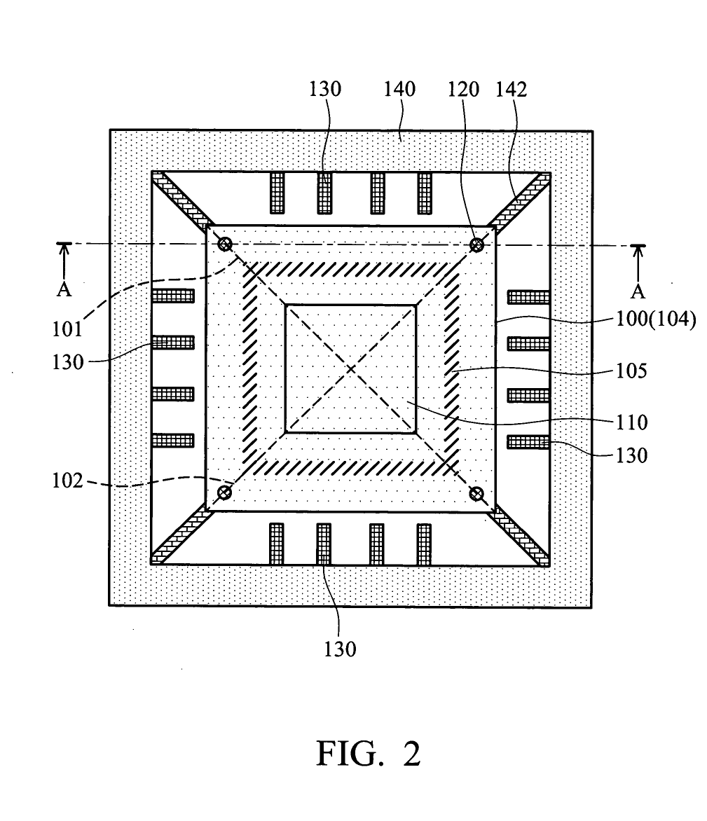

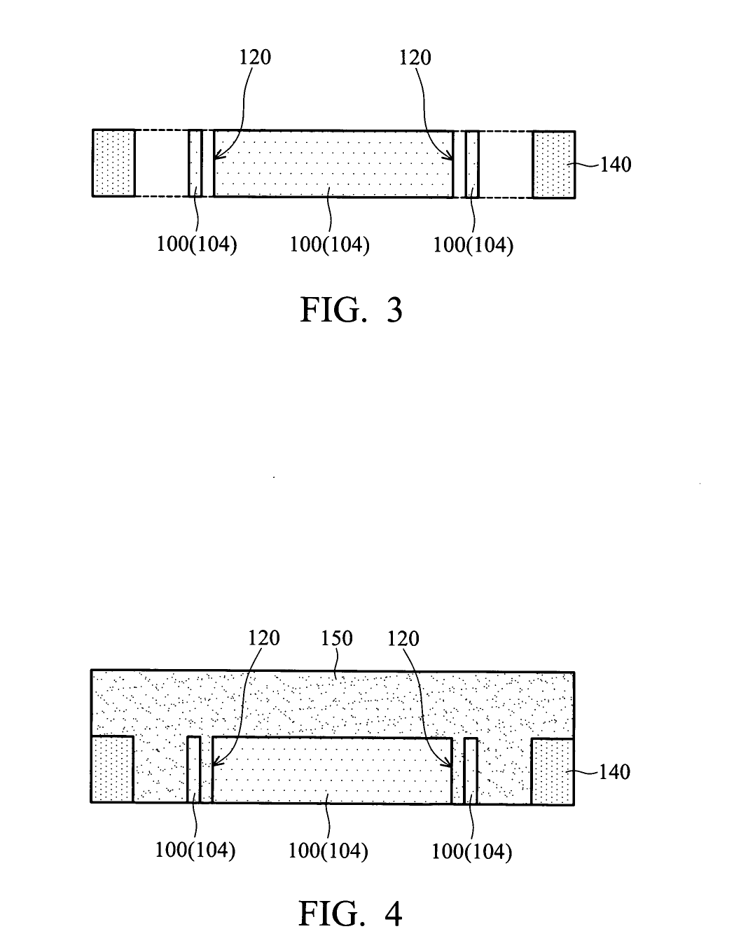

FIG. 2 is a top view of an active device base and a leadframe of a preferred embodiment of the invention, and FIG. 3 is a cross-section along line AA in FIG. 2.

Referring to FIG. 2, the inventive active base 100 comprises a plate 104, preferably of a conductive material, to act as a grounding element for an active device (not shown) predetermined for attachment thereto. The plate 104 is more preferably metal when utilized by a leadframe. The plate 104 comprises a predetermined attachment area 110 for the active device. The plate 104 further comprises at least one through hole 120 in the plate 104, beyond the predetermined attachment area 110 and substantially extending through the plate 104.

The inventive leadframe comprises the inventive active base 100, a plurality of terminals 130, and a peripheral boundary 140. The terminals 130 are disposed beyond the plate 100 and between the plate 100 and the peripheral boundary 140, connected to the peripheral boundary 140. Further, the peripheral boundary 140 is connected to the plate 100 via supporters 142.

The through hole 120 is typically formed by punching utilizing a punch head of predetermined shape and size. In this embodiment, the through hole 120 is substantially round. In other embodiments, the through hole can be rectangular, polygonal, stellar, or other shapes, formed by punch utilizing a corresponding punch head as desired.

Further, an optional wire-bonding area 105 can be formed outside the predetermined attachment area 110 as desired. When an active device is attached to the predetermined attachment area 110, the active device and the wire-bonding area 105 can be electrically connected by a conventional wire bonding process, grounding the active device. Gold wires are typically utilized to electrically connect the active device and the base 100, and thus, an adhering layer (not shown), comprising excellent adhesion with both the plate 104 and gold, is typically plated on the plate 104 in the wire-bonding area 105. When the plate 104 comprises copper, for example, the adhering layer can comprise a nickel/gold layer, a nickel/palladium/gold layer, or other suitable materials. At this time, the through hole 120 is arranged outside the wire-bonding area, at a side different from the predetermined attachment area 110.

The advantages introduced by the through hole 120 are shown in FIG. 4. In FIG. 4, following FIG. 3, an encapsulant 150 is formed overlying the inventive leadframe. The encapsulant 150 enters and fills the through hole 120 during an encapsulation process, and thus, the encapsulant 150 tightly nails on the active device base 100, increasing the adhesion therebetween, thereby preventing delamination therebetween due to exertion of thermal stress. As a result, the reliability of a product utilizing the inventive active base and leadframe can be improved.

After encapsulation, the bottom surfaces of the active device base 100 and the terminals 130 shown in FIG. 2 are exposed by the encapsulation 150. The resulting package is electrically connected to a circuit board of a product via the exposed active device base 100 and terminals 130 by conventional surface mount technology utilizing a solder material comprising tin-based alloys as an adhesive. The encapsulant 150 typically comprises a mixture of epoxy and silica fillers, and thus, the solder material can neither wet nor solder the encapsulant 150. As a result, the formation of the through hole 120 potentially deceases the effective adhering area between the active device base 100 and the circuit board. Therefore, the opening area of the through hole 120 on the plate 104 is preferably limited to prevent substantially reducing the adhesion between the active device base 100 and the circuit board. In this embodiment, the adhesion between the active device base 100 and the circuit board is not substantially reduced when the opening area of the through hole 120 is as large as the area of the plate 104 or less.

Preferably, a plurality of the through holes 120 can be formed in order to further improve the product reliability introduced by the invention. The thermal stress exerting on the package induced by the thermal process, reliability test, thermal cycling, or other factors is typically isotropic. Thus, the plurality of the through holes 120 are preferably substantially symmetrically arranged in the plate 104 utilizing the geometrical center of the plate 104 as a reference point for an equilibrium of adhesion improvement to resist the thermal stress. In this embodiment, the inventive active base 100 comprises four through holes 120 as shown in FIG. 2. Further, the thermal stress distribution on the plate 104 typically shows positive gradients from the geometrical center to corners or edges thereof. Thus, the effect of reliability improvement rises as the through holes 120 are farther away from the geometrical center of the plate 104.

In this embodiment, the plate 104 is substantially rectangular. In other embodiments, the plate 104 can be polygonal or other shapes as desired. In FIG. 2, the four comer areas near the diagonals 101 and 102 are the farthest away from the geometrical center of the plate 104, and thus, the relatively highest thermal stress exerts thereon when the thermal is stress is induced. As a result, the four through holes 120 are preferably respectively disposed at the four comers of the plate 104. Moreover, the effect of reliability. improvement rises when the diagonals 101 and 102 respectively substantially pass the through holes 120.

Similarly, a sum of the opening areas of the through holes 120 on the plate 104 is preferably as large as the area of the plate 104 or less to prevent substantially reducing the adhesion between the active device base 100 and the circuit board. The individual opening area of every through hole 120 is reversely proportional to the quantity thereof. When the opening area of one of the through holes 120 is too small to hold the silica fillers of the encapsulant 150, the encapsulant 150 cannot fill the corresponding through hole 120, leaving voids therein. As a result the product reliability cannot be improved, but in the contrary, decreases due to the popcorn effect occurred during the thermal process such as surface mount technology, reliability tests, thermal cycling, or other thermal processes, resulting from the quick and sharp volume increases of the gas or liquid droplets accumulating in the voids. Thus, the required quantity of through holes 120 preferably depends on the process requirement and the properties of the encapsulant 150. In this embodiment, the active device base 100 preferably comprises four through holes 120 when the plate 104 is substantially rectangular.

The efficacy of the inventive active device bases and leadframes at improving the adhesion between the encapsulants and the bases, provide improved device reliability.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An active device base, comprising:
a plate;
a predetermined attachment area for an active device on a surface of the plate; and
at least one through hole in the plate, beyond the predetermined attachment area.

2. The base as claimed in claim 1, wherein the plate further comprises a wire-bonding area outside the predetermined attachment area, and the through hole is outside the wire-bonding area.

3. The base as claimed in claim 1, wherein the active device base comprises a plurality of the through holes substantially symmetrically arranged in the plate utilizing the geometrical center thereof as a reference point.

4. The base as claimed in claim 1, wherein the plate is substantially rectangular, and the active device base comprises four through holes substantially symmetrically arranged in the plate utilizing the geometrical center thereof as a reference point.

5. The base as claimed in claim 4, wherein diagonals of the plate substantially pass the through holes.

6. The base as claimed in claim 1, wherein an opening area of the through hole is as large as five percent of the area of the plate or less.

7. The base as claimed in claim 3, wherein a sum of the opening areas of the through holes is as large as five percent of the area of the plate or less.

8. The base as claimed in claim 4, wherein a sum of the opening areas of the through holes is as large as five percent of the area of the plate or less.

9. A leadframe, comprising:
a plate;
a predetermined attachment area for an active device on a surface of the plate;
at least one through hole in the plate, beyond the predetermined attachment area;
a plurality of terminals beyond the plate; and
a peripheral boundary sandwiching the terminals with the plate, connected to the respective plate and the terminals.

10. The leadframe as claimed in claim 9, wherein the plate further comprises a wire-bonding area outside the predetermined attachment area, and the through hole is outside the wire-bonding area.

11. The leadframe as claimed in claim 9, wherein the active device base comprises a plurality of the through holes substantially symmetrically arranged in the plate utilizing the geometrical center thereof as a reference point.

12. The leadframe as claimed in claim 9, wherein the plate is substantially rectangular, and the active device base comprises four through holes substantially symmetrically arranged in the plate utilizing the geometrical center thereof as a reference point.

13. The leadframe as claimed in claim 12, wherein diagonals of the plate substantially pass the through holes.

14. The leadframe as claimed in claim 9, wherein an opening area of the through hole is as large as five percent of the area of the plate or less.

15. The leadframe as claimed in claim 11, wherein a sum of the opening areas of the through holes is as large as five percent of the area of the plate or less.

16. The leadframe as claimed in claim 12, wherein a sum of the opening areas of the through holes is as large as five percent of the area of the plate or less.
